(19) United States
(12) Patent Application Publication
(10) Pub. No.: US 2025/0253271 A1
(43) Pub. Date: Aug. 7, 2025

(54) INTEGRATING HIGH PERMEABILITY MATERIAL IN SOLDER BALL CONNECTION

(71) Applicant: Cisco Technology, Inc., San Jose, CA (US)

(72) Inventors: Yuqing ZHU, Shanghai (CN); Wenbin MA, Shanghai (CN); Mike SAPOZHNIKOV, San Jose, CA (US); Haiying ZHU, Shanghai (CN); Mingtong ZUO, Shanghai (CN); Shuo ZHANG, Shanghai (CN); Tianyi ZHOU, Shanghai (CN); D. Brice ACHKIR, Livermore, CA (US)

(21) Appl. No.: 18/430,636

(22) Filed: Feb. 1, 2024

(51) Int. Cl. H01L 23/64; H01L 21/56; H01L 23/00; H01L 23/29; H01L 23/31

(52) U.S. Cl. CPC H01L 23/645; H01L 21/56; H01L 23/293; H01L 23/3171; H01L 23/3192; H01L 24/16; H01L 24/27; H01L 24/29; H01L 24/32; H01L 24/73; H01L 24/81; H01L 2224/16227; H01L 2224/16238; H01L 2224/2741; H01L 2224/2916; H01L 2224/32225; H01L 2224/73204; H01L 2224/81815; H01L 2924/30105; H01L 2924/30107

(57) ABSTRACT

Embodiments herein describe disposing a magnetic material (e.g., a high permeability material) in a solder ball connection between two substrates (e.g., between an integrated circuit (IC) and a printed circuit board (PCB)). After a reflow process (which bonds two substrates together using solder balls), the solder balls become spherical, which causes the distance between two neighboring solder balls to decrease, which increases capacitance. The magnetic material can counterbalance the negative effects of the increased capacitance.

### TECHNICAL FIELD

Embodiments presented in this disclosure generally relate to disposing high permeability material in a solder ball connection between two substrates.

### BACKGROUND

Solder joints play a critical role in ball grid array (BGA) chip bonding and signal integrity. For example, the solder balls forming the solder joints can contribute to crosstalk, reflection, and insertion loss.

### BRIEF DESCRIPTION OF THE DRAWINGS

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate typical embodiments and are therefore not to be considered limiting; other equally effective embodiments are contemplated.

FIGS. 1A and 1B illustrate disposing a thin layer of high permeability material in a solder ball connection, according to embodiments described herein.

FIG. 2 illustrates disposing high permeability material in a solder ball connection, according to an embodiment described herein.

FIG. 3 is a flowchart for disposing a thin layer of high permeability material in a solder ball connection, according to an embodiment described herein.

FIGS. 4A and 4B illustrate examples of performing the blocks in the flowchart of FIG. 3, according to embodiments described herein.

FIG. 5 is a flowchart for dispensing high permeability material into a solder ball connection, according to an embodiment described herein.

FIG. 6 illustrates an example of performing one of the blocks in the flowchart of FIG. 5, according to embodiments described herein.

FIG. 7 illustrates disposing a polyimide layer and a high permeability layer in a solder ball connection, according to an embodiment described herein

FIG. 8 illustrates return loss of various structures, according to an embodiment described herein.

FIG. 9 illustrates transient device properties of various structures, according to an embodiment described herein.

To facilitate understanding, identical reference numerals have been used, where possible, to designate identical elements that are common to the figures. It is contemplated that elements disclosed in one embodiment may be beneficially used in other embodiments without specific recitation.

### DESCRIPTION OF EXAMPLE EMBODIMENTS

### Overview

One embodiment presented in this disclosure is a system that includes an integrated circuit (IC) and a printed circuit board (PCB). Further, solder balls connect the IC to the PCB and a magnetic material is disposed in a first space between the IC and the PCB and a second space between the solder balls such that the magnetic material surrounds the solder balls.

One embodiment presented in this disclosure is a method that includes laminating a thin film of magnetic material onto a surface of an IC or a PCB and bonding the IC to the PCB using solder balls such that the thin film is disposed in a space between the IC and the PCB and between the solder balls.

One embodiment presented in this disclosure is a method that includes bonding an IC to a PCB using solder balls and dispensing a magnetic material to fill a region between the solder balls.

### Example Embodiments

Embodiments herein describe disposing a high permeability material in a solder connection between two substrates (e.g., between an integrated circuit (IC) and a printed circuit board (PCB)). After a reflow process (which bonds two substrates together using solder balls), the solder balls become spherical, which causes the distance between two neighboring solder balls to decrease. This contributes to a greater capacitive coupling between a solder ball and its neighbors. Moreover, the spherical solder balls lead to additional capacitive coupling between a PCB top side pin pad and the bottom of an IC (or chip). When the data rate reaches speeds at or above 112G or 224G, the signal channel may experience impedance mismatch caused by a solder ball, a plated through-hole (PTH) via, and a PTH via to trace transition. At certain frequencies, the impedance at the solder balls drops sharply which disadvantageously causes return loss (RL) and insertion loss to increase significantly. The solder ball impedance and reflection can become the bottleneck of the signal channels between the two substrates.

The embodiments herein describes a solder ball arrangement for compensating for the impedance and reflection loss caused by spherical solder balls. Namely, a magnetic material (e.g., a high permeability material) is disposed within the solder ball connection which increases the inductance of the solder ball to balance the extra capacitance caused by the spherical solder balls, thereby making the corresponding impedance curve flatter and improving RL. In one embodiment, the high permeability material is a thin film that is applied (e.g., laminated) onto one of the substrates before the solder connection is made. In another embodiment, the high permeability material is dispensed in a liquid state using a capillary effect after the solder connection is made. The liquid high permeability, after a certain period of standing or heating, undergoes water evaporation inside, transforming into a solid state.

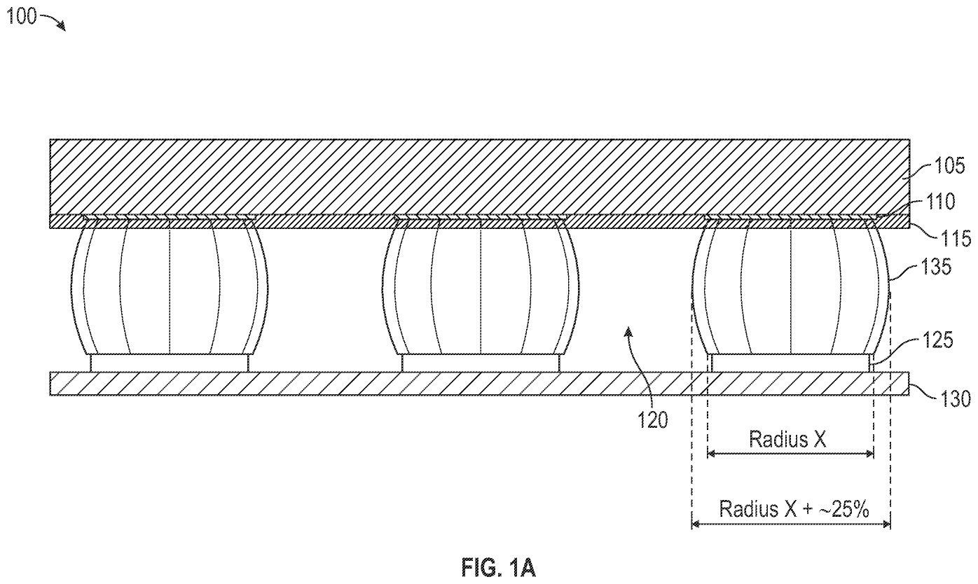

FIGS. 1A and 1B illustrate disposing a thin layer of high permeability material in a solder ball connection, according to embodiments described herein. FIG. 1A illustrates a solder ball connection 100 that includes a substrate 105 (e.g., an IC, chip, silicon interposer, another PCB, etc.) coupled to a PCB 130 using solder balls 135. The solder balls 135 can provide both mechanical and electrical connections between the substrate 105 and the PCB 130. The substrate 105 can include electrical circuitry, optical components, traces, vias, and the like. The PCB 130 can include any number of conductive and insulating layers that are laminated in a stack. The PCB 130 can include traces within the layers and vias (e.g., PTH vias) that extend between the layers.

The solder balls 135 can be used to form various types of electrical connections. For example, some of the solder balls may be used to form high speed signal connections (e.g., speeds at or above 112G or 224G). The high speed signal connections may use two neighboring solder balls 135 that form a differential pair. The solder balls 135 forming the high speed connection may be surrounded by solder balls 135 that are grounded. In addition, the solder ball connection 100 can include solder balls 135 that are used to carry power signals (e.g., direct current (DC) power signals rather than alternating current (AC) data signals). Further, some solder balls 135 may not be used to form any electrical connections but may be dummy solder balls used only for mechanical support.

The substrate 105 includes substrate bond pads 110 for connecting to a top side of the solder balls 135 while the PCB 130 includes PCB bond pads 125 for connecting to the bottom side of the solder balls 135. Further, in this embodiment, there is an air gap 120 between the solder balls 135.

The solder balls 135 include a substantially spherical shape in the region between the substrate bond pad 110 and the PCB bond pad 125. For example, the radius X of the solder balls 135 at the bond pad 125 expands in the direction towards the substrate bond pad 110 until reaching the middle of the solder ball 135. In this case, the radius X of the solder ball 135 can increase by approximately 25% (e.g., from 20-30%) at the middle of the solder ball 135 relative to the top and bottom of the solder ball 135. As such, the distance between the edges of neighboring solder balls 135 can be much shorter at the middle of the solder balls 135 than at the tops or bottoms of the solder balls 135 where they contact the bond pads 110, 125. This contributes to a greater capacitive coupling between a solder ball and its neighbors. Moreover, the spherical solder balls 135 lead to additional capacitive coupling between a top side bond pad 125 of the PCB 130 and the bottom bond pad 110 of the substrate 105. If not compensated for, this additional capacitance can cause RL and insertion loss to increase significantly.

To reduce the capacitive coupling, the solder ball connection 100 includes a high permeability layer 115 that is disposed on the bottom side of the substrate 105. The high permeability layer 115 can include a magnetic material. In one embodiment, the magnetic material is a ferrous material. For example, the high permeability layer 115 can include nickel, iron, or combinations thereof.

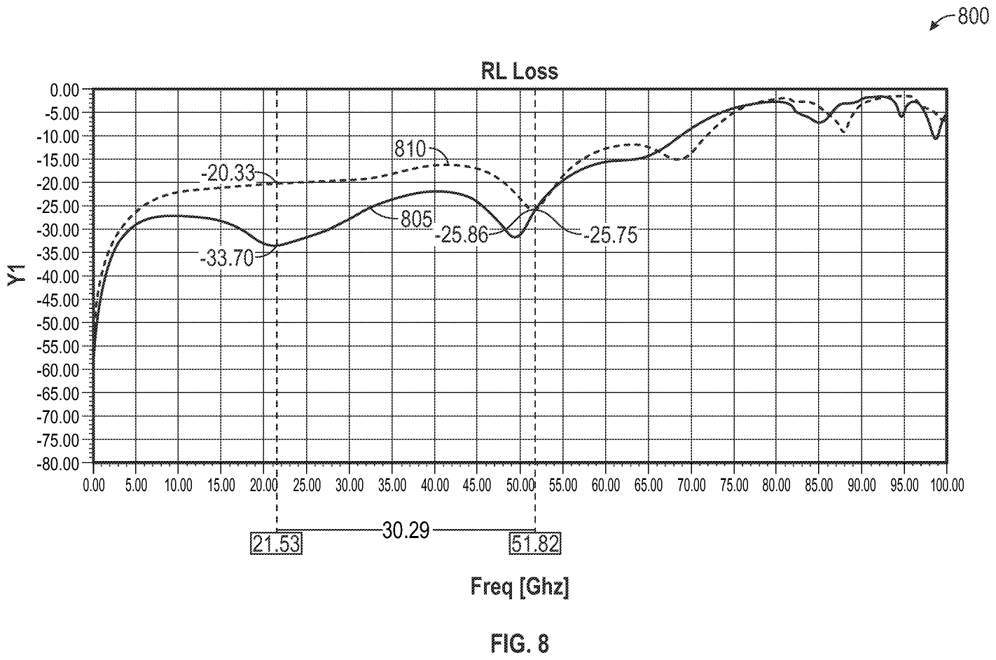

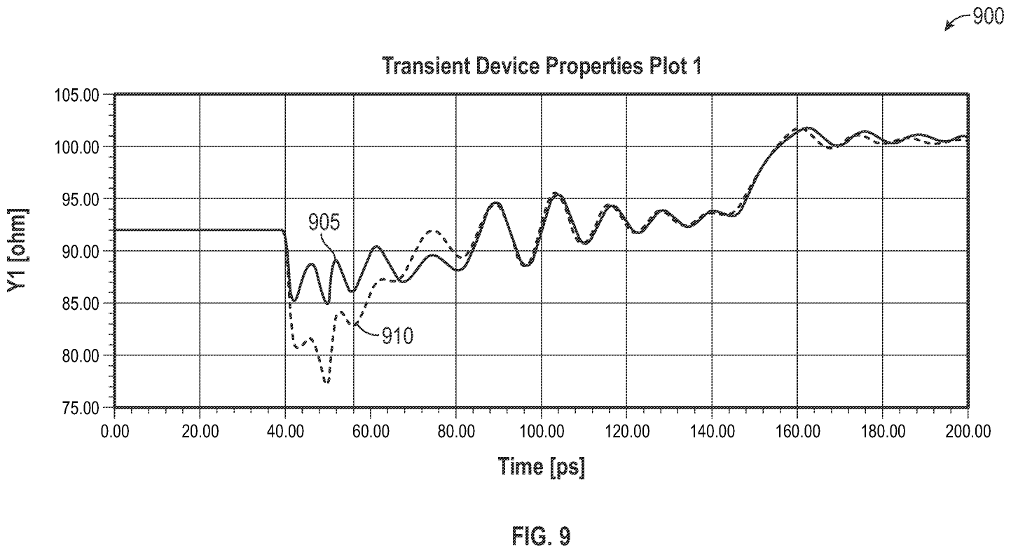

By placing the high permeability layer 115 between the substrate 105 and the PCB 130 and between the solder balls 135, the layer 115 can increase magnetic flux and inductance in order to counterbalance the capacitance caused by the spherical solder balls 135. The high permeability layer 115 can improve RL and insertion loss and result in a flatter impedance curve. This is discussed in more detail in FIGS. 8 and 9 below.

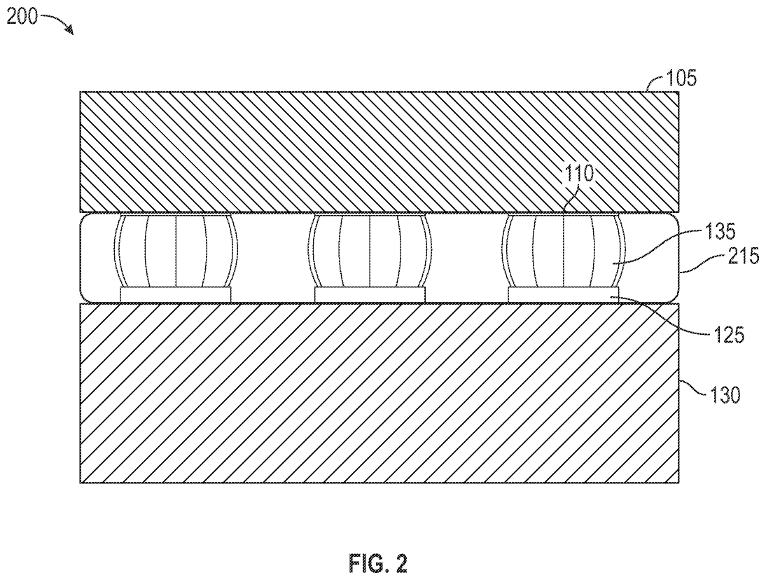

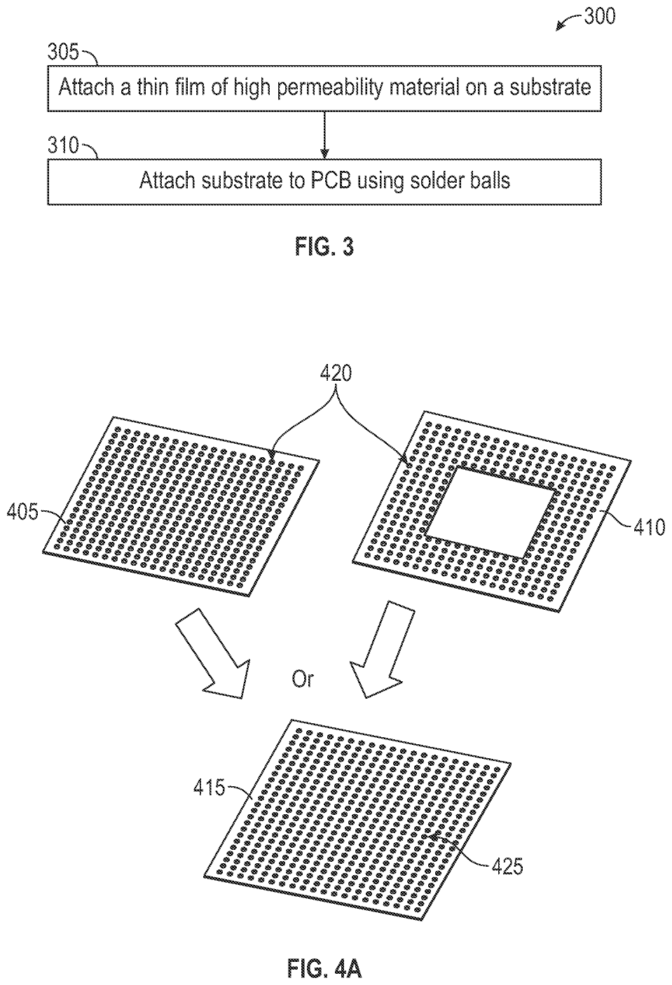

In one embodiment, the high permeability layer 115 is disposed on the substrate 105 before the solder ball connection between the substrate 105 and the PCB 130 is formed. An example method of forming the solder ball connection 100 is discussed in FIGS. 3 and 4A-4B below.

FIG. 1B illustrates a solder ball connection 150 that includes many of the same components as FIG. 1A as indicated by using the same reference numbers. However, unlike in FIG. 1A where the high permeability layer was disposed on the substrate 105, in FIG. 1B a high permeability layer 155 is disposed on the PCB 130. Regardless whether the high permeability layer 155 is disposed on the substrate 105 or the PCB 130, it can result in the advantages discussed above.

In one embodiment, the thickness of the high permeability layers in FIGS. 1A and 1B can vary. For example, the thickness can depend on the size of solder ball 135, the frequency of interest (e.g., the frequency of the high speeds signals that use the solder balls 135) and the size of the substrate 105 and/or PCB 130 (e.g., the size of the IC or chip). Thus, while the high permeability layers in FIGS. 1A and 1B are shown as being approximately the same thickness as the bond pads 110 and 125, they may be thicker than the bond pads, or in some instances, may be thinner than the bond pads.

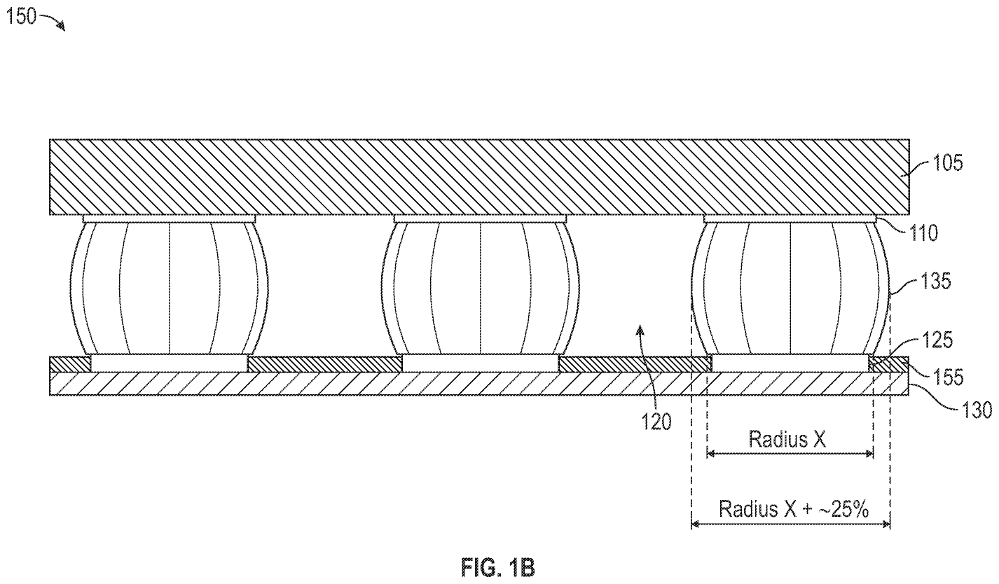

FIG. 2 illustrates disposing high permeability material in a solder ball connection 200, according to an embodiment described herein. The solder ball connection 200 includes many of the same components discussed in FIGS. 1A and 1B as indicated by using the same reference numbers. However, instead of having a thin layer of high permeability material, the solder ball connection 200 includes a high permeability layer 215 that occupies much of the space between the solder balls 135. The high permeability layer 215 can include any of the materials discussed above.

In one embodiment, the solder ball connection 200 is made by dispensing a high permeability material in a liquid state. A capillary effect due to the small spacing between the substrate 105 and the PCB 130 can distribute the high permeability material between the solder balls. In one embodiment, the high permeability material surrounds each of the solder balls 135. The liquid high permeability, after a certain period of standing or heating, undergoes water evaporation inside, transforming into a solid state.

Further, FIG. 2 can show an idealized illustration where the high permeability material completely fills the space between the substrate 105 and the PCB 130. The high permeability material can still fill the space between the substrate 105 and the PCB 130 even if there are some air pockets between the solder balls 135.

FIG. 3 is a flowchart of a method 300 for disposing a thin layer of high permeability material in a solder ball connection, according to an embodiment described herein. For ease of explanation, the method 300 is discussed in conjunction with FIGS. 4A and 4B.

At block 305, a thin film of high permeability material is attached to a substrate. For example, FIG. 4A illustrates attaching two different types of thin films of high permeability material to a substrate 415. The substrate 415 could be the substrate 105 or the PCB 130 illustrated in FIGS. 1-2 above.

FIG. 4A illustrates a first type of thin film 405 and a second type of thin film 410, either of which could be attached to the substrate 415 using an adhesive or other type of attachment technique. As shown, both types of thin films 405, 410 include apertures 420 (or through holes) which align with bond pads 425 on the substrate 415. That is, the pitch of the apertures 420 may be the same as the pitch on the bond pads 425 so that when the apertures 420 are aligned with the substrate 415, each bond pad 425 is aligned with an aperture 420. That way, a solder ball can later be placed on the bond pad 425 without being blocked by the thin film. Depending on the thickness of the thin films 405, 410, the bond pads may protrude through the apertures 420.

The thin film 405 includes an aperture for each of the bond pads 425, however, in contrast the thin film 410 includes an aperture for only the bond pads 425 at the periphery of the substrate 415 and not the bond pads in the center of the substrate 415. There can be advantages and disadvantages of both types of thin films. For example, the thin film 405 may experience less warpage since it extends across the entire surface of the substrate 415 when attached. However, the thin film 405 also places the high permeability material at the center of the substrate 415 that includes bond pads 425 that are typically used for power signals. It is advantageous for power signals to have as much capacitance as possible, which, as discussed above, the high permeability material will reduce.

In contrast, the thin film 410 does not place high permeability material at the center of the substrate 415, and as such, has little to no effect on the power signals made using the bond pads 425 at the center of the substrate 415. However the thin film 410 may experience more warpage than the thin film 405 due to the absence of material at its center.

Returning to the method 300, at block 310 the substrate is attached to a PCB using solder balls. One example of this is illustrated in FIG. 4B where the substrate 415 from FIG. 4A is attached to solder balls 135 on the PCB 130. For example, when the bond pads 425 are aligned with the solder balls 135, a reflow soldering process can be employed to attach the solder balls 135 to bond pads 425. In this process, the solder paste is applied to the bond pads 125 on the PCB, and then melted by heat gun, creating solder joints as the connection between bond pads 425 and 125.

While FIG. 4B illustrates the solder balls 135 having a spherical shape, the balls 135 may not have a spherical shape until after the reflow process when the solder balls 135 are attached to the substrate 415.

Moreover, while FIG. 4B illustrates that the solder balls 135 are first deposited on the PCB 130, in another embodiment, the solder balls 135 may first be deposited on the substrate 415 while the thin film 405 or the thin film 410 is attached to the PCB 130. The reflow process can then be used to attach the solder balls 135 to the PCB bond pads 125.

As shown in FIGS. 4A and 4B, the thin film of high permeability material is disposed between the substrate 415 and the PCB 130. Moreover, the high permeability material (e.g., a magnetic and/or ferrous material) is disposed between the solder balls 135, and surrounds the solder balls. However, if the thin film 410 is used, the high permeability material may not be disposed between (and surround) all of the solder balls 135 forming the solder ball connection between the substrate 415 and the PCB 130. That is, the thin film 410 has a large aperture in the middle so that the magnetic material is not disposed near solder balls tasked with delivering power near the center.

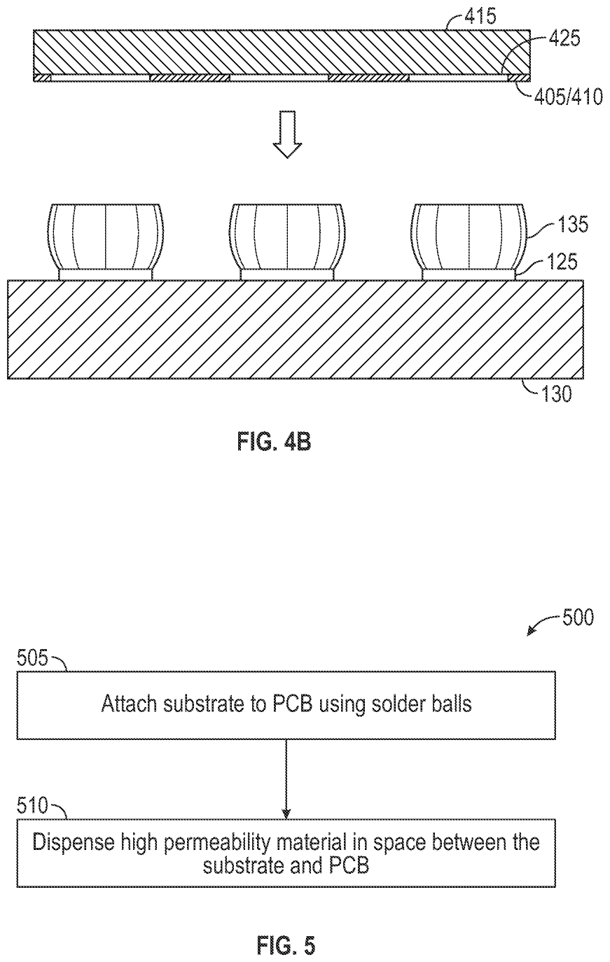

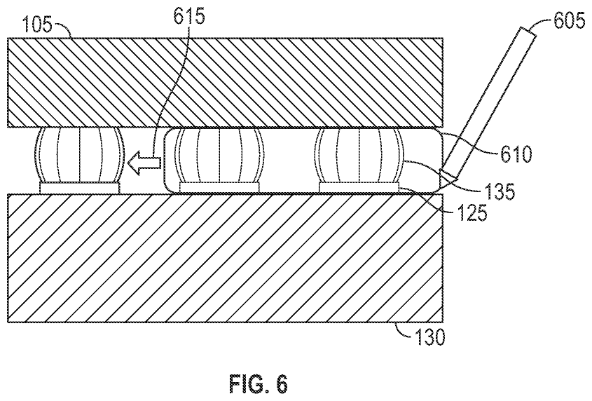

FIG. 5 is a flowchart of a method 500 for dispensing high permeability material into a solder ball connections, according to an embodiment described herein. For ease of explanation, the method 500 is discussed in conjunction with FIG. 6.

At block 505, a substrate is attached to a PCB using solder balls. At block 510, high permeability material is dispensed in the space between the substrate and the PCB where the solder ball connections are formed. This is illustrated in FIG. 6 where a solder ball connection has already been made between the substrate 105 and the PCB 130. FIG. 6 also illustrates a dispenser 605 that injects high permeability material 610 into the space between the substrate 105 and the PCB 130, and between the solder balls 135.

The arrow 615 illustrates the high permeability material 610 spreading away from the dispenser and continuing to fill the air gap between the solder balls 135. In one embodiment, a capillary effect may be used to distribute the high permeability material in a liquid state such that is surrounds the solder balls 135. While FIGS. 2 and 6 illustrate filling the entire space between the substrate 105 and the PCB 130, in other embodiments there may be air gaps. Moreover, because it may not be desirable to have the high permeability material 610 near power signals near the center of the substrate 105 and the PCB 130, the dispenser 605 may be controlled to apply the high permeability material 610 only at the periphery so that the material 610 does not spread to reach the solder balls 135 near the center of the substrate 105 (similar to using the thin film 410 in FIG. 4A).

When the high permeability material 610 has been dispensed, the material 610 may change into a solid state to form the high permeability layer 215 shown in FIG. 2.

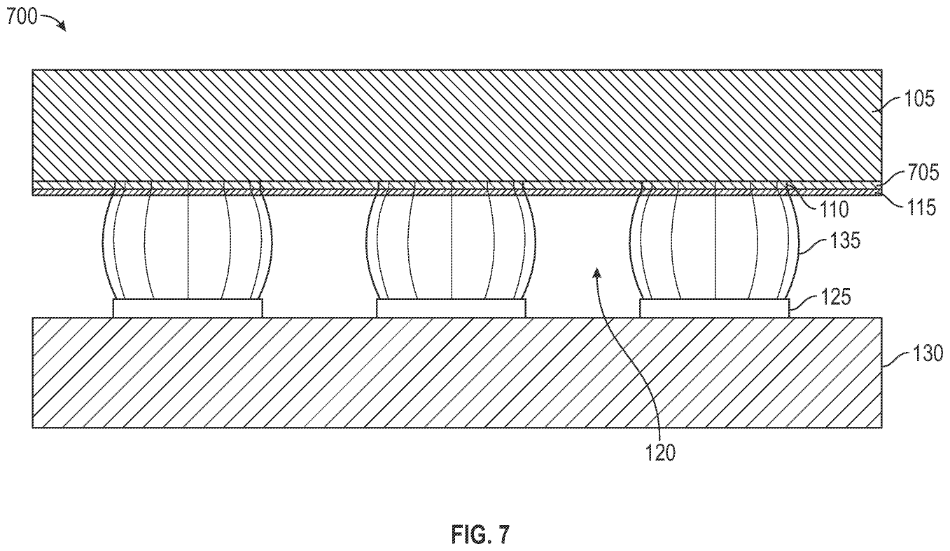

FIG. 7 illustrates disposing a polyimide layer 705 and a high permeability layer 115 in a solder ball connection 700, according to an embodiment described herein. As shown, the polyimide layer 705 is disposed between the high permeability layer 115 and the substrate 105. If a high permeability layer is instead disposed on the PCB 130 as shown in FIG. 1B, then the polyimide layer 705 can be disposed between the high permeability layer and the PCB 130.

In general, the polyimide layer 705 serves as a barrier layer between the high permeability layer 115 and the underlying substrate 105 (or PCB 130). Because of the high temperatures used during the reflow process, these high temperatures may cause the material of the high permeability layer 115 to contaminate the substrate 105. For example, the substrate 105 may be an IC or chip with sensitive electronic circuitry that can be harmed by the material in the high permeability layer 115. The polyimide layer 705 is a high-temperature resistant layer that prevents any material of the high permeability layer 115 from contaminating the substrate 105.

In one embodiment, multiple barrier layers formed by the polyimide layer 705 can be used when dispensing the high permeability material in FIGS. 5 and 6. In that scenario, a polyimide layer 705 can be disposed on both surfaces of the IC and PCB so that when dispensing the high permeability material it does not contaminate the IC or the PCB.

FIG. 8 is a chart 800 that illustrates RL of various structures, according to an embodiment described herein. Specifically, the chart 800 is simulation data that illustrates a plot 805 for a solder ball connection that includes a thin film of high permeability material as shown in FIG. 1A or 1B and a plot 810 for a solder ball connection where the thin film of high permeability material is omitted.

In generally, the lower the RL loss, the better signal performance is achieved. The chart illustrates that the plot 805 has improved RL loss compared to plot 810 for the frequencies between 5 GHz to 53 GHZ. The RL loss for the plots 805 and 810 are similar for higher frequencies. In any case, the chart 800 illustrates that adding a thin film of magnetic material as represented by plot 805 can significantly improve the signal integrity for 224G Serializer/Deserializer (SerDes).

FIG. 9 illustrates transient device properties of various structures, according to an embodiment described herein. For example, the transient device property can be time-domain reflectometry (TDR). Specifically, the chart 900 is simulation data that illustrates a plot 905 for a solder ball connection that includes a thin film of high permeability material as shown in FIG. 1A or 1B and a plot 910 for a solder ball connection where the thin film of high permeability material is omitted.

Plot 905 illustrates a much less dramatic drop in impedance at 40 ps than the plot 910. As such, the impedance curve defined by plot 905 is much flatter than the impedance curve defined by plot 910. Thus, the chart 900 illustrates that adding a thin film of magnetic material as represented by plot 905 can significantly improve the signal integrity for 224G Serializer/Deserializer (SerDes).

In the current disclosure, reference is made to various embodiments. However, the scope of the present disclosure is not limited to specific described embodiments. Instead, any combination of the described features and elements, whether related to different embodiments or not, is contemplated to implement and practice contemplated embodiments. Additionally, when elements of the embodiments are described in the form of “at least one of A and B,” or “at least one of A or B,” it will be understood that embodiments including element A exclusively, including element B exclusively, and including element A and B are each contemplated. Furthermore, although some embodiments disclosed herein may achieve advantages over other possible solutions or over the prior art, whether or not a particular advantage is achieved by a given embodiment is not limiting of the scope of the present disclosure. Thus, the aspects, features, embodiments and advantages disclosed herein are merely illustrative and are not considered elements or limitations of the appended claims except where explicitly recited in a claim(s). Likewise, reference to “the invention” shall not be construed as a generalization of any inventive subject matter disclosed herein and shall not be considered to be an element or limitation of the appended claims except where explicitly recited in a claim(s).

In view of the foregoing, the scope of the present disclosure is determined by the claims that follow.

We claim:

1. A system, comprising:
an integrated circuit (IC); and
a printed circuit board (PCB), wherein solder balls connect the IC to the PCB, wherein a magnetic material is disposed in a first space between the IC and the PCB and a second space between the solder balls such that the magnetic material surrounds the solder balls.

2. The system of claim 1, wherein the magnetic material is a ferrous material.

3. The system of claim 1, wherein the magnetic material is a thin film deposited onto a surface of the IC or the PCB.

4. The system of claim 3, wherein the thin film is laminated onto the surface of the IC or the PCB using an adhesive.

5. The system of claim 3, further comprising:
a barrier layer disposed between the thin film and the surface of the IC or the PCB that prevents the magnetic material in the thin film from contaminating the IC or the PCB when the solder balls undergo a reflow process.

6. The system of claim 5, where the barrier layer is a polyimide layer.

7. The system of claim 1, wherein the magnetic material extends between the IC and the PCB such that the magnetic material fills the first space between the IC and the PCB that includes the solder balls.

8. The system of claim 1, wherein the magnetic material is not disposed in a region of the system containing solder balls used for power connections between the IC and the PCB.

9. A method, comprising:
laminating a thin film of magnetic material onto a surface of an IC or a PCB; and
bonding the IC to the PCB using solder balls such that the thin film is disposed in a space between the IC and the PCB and between the solder balls.

10. The method of claim 9, wherein laminating the thin film of magnetic material comprising using an adhesive to attach the thin film to the surface of the IC or the PCB.

11. The method of claim 9, wherein the thin film of magnetic material comprises apertures that each aligns with a respective bond pad on the surface of the IC or the PCB.

12. The method of claim 9, wherein the magnetic material is a ferrous material.

13. The method of claim 9, further comprising, before laminating the thin film:
disposing a barrier on the surface of the IC or the PCB that prevents the magnetic material in the thin film from contaminating the IC or the PCB when the solder balls undergo a reflow process.

14. The method of claim 9, wherein the thin film comprises an aperture in a center so that the magnetic material is not disposed in a region of the IC and the PCB used for power connections between the IC and the PCB.

15. A method, comprising:
bonding an IC to a PCB using solder balls; and
dispensing a magnetic material to fill a region between the solder balls.

16. The method of claim 15, wherein the magnetic material is in a liquid state and is spread through the region between the solder balls using a capillary effect.

17. The method of claim 15, wherein the magnetic material is spread through the region between the solder balls using a capillary effect.

18. The method of claim 15, wherein the magnetic material is a ferrous material.

19. The method of claim 15, wherein the magnetic material is not disposed in a region containing solder balls used for power connections between the IC and the PCB.

20. The method of claim 15, further comprising, before dispensing the magnetic material:
forming barrier layers on surfaces of the IC and the PCB.
